(19) United States
(12) Patent Application Publication
(10) Pub. No.: US 2006/0068576 A1
(43) Pub. Date: Mar. 30, 2006

(54) Lithography transfer for high density interconnect circuits

(76) Inventors: William Edward Burdick JR., Niskayuna, NY (US); James Wilson Rose, Guilderland, NY (US); Kevin Matthew Durocher, Waterford, NY (US); James Enrico Sabatini, Scotia, NY (US)

Correspondence Address: Patrick S. Yoder;FLETCHER YODER, P.O. Box 692289, Houston, TX, 77269-2289, US

(21) Appl. No.: 10/955,408

(22) Filed: Sep. 30, 2004

(51) Int. Cl. H01L 21/3205

(52) U.S. Cl. 438/586

(57) ABSTRACT

A method for fabricating an interconnect comprising providing a carrier substrate, wherein the carrier substrate comprises a plurality of interconnect traces and a plurality of input/output contacts; providing a flexible substrate having a first side and a second side, disposing the second side of the sacrificial layer onto the first side of the flexible substrate to form a first assembly, disposing the carrier substrate onto the first assembly; and removing the sacrificial layer and the carrier substrate to form the interconnect. A detector for use in an imaging system comprises the aforementioned interconnect.

### BACKGROUND

The invention relates generally to the field of electronic interconnect systems, and more particularly to transfer lithography for high density interconnect circuits.

Integrated circuit functionality and complexity increase in tandem with ever shrinking device and electronic package geometries and footprints. Today, integrated circuit devices can be fabricated with features as small as 0.1 microns, with input/output pads as small as 0.2 micron pitch, or less. Input/output pad geometry and configuration for these devices are typically according to minimum interconnect features. That is to say that the input/output pad features and configuration are conventionally determined by an interconnect pitch and/or configuration capability, rather than a device or wafer capability.

Higher density multi-layer flexible circuits with finer signal trace pitches (e.g., less than 0.100 mm) have been fabricated for use in interconnect devices. Currently, the practical limit of interconnect pitch for multi-layer, flexible circuits available from commercial suppliers is approximately 0.100 mm with some capability in finer pitches (e.g., less than 100 mm) in prototype to low manufacturing volumes. Although alternative high density, fine pitch interconnect systems are contemplated, (e.g., carbon nanotubes), there currently exists an impediment or density barrier to interconnecting high density input/output devices to “systems.” This impediment results from functional performance, capability, and cost limitations of existing interconnect systems. In general, flexible printed circuits, i.e., flex interconnects, are constructed using thinner dielectrics and metals with finer geometries, and hence, flex interconnects typically allow for the circuit patterning at higher density as compared to their rigid counterparts. In the laboratory, multi-layer flexi interconnects with trace pitches as low as 0.030 mm pitch can be fabricated. However, even the most advanced flex interconnect technologies may be limited in achieving trace pitches under 0.030 mm due to the structural changes of the flex material during downstream processing and fabrication.

During a flexible printed circuit interconnect fabrication process implementing a flex (e.g., polyimide) substrate, the polymer base films are subjected to temperatures and mechanical forces that cause the polyimide to stretch, shrink and otherwise change in physical dimensions both during and upon completion of processing. These dimensional changes and instability can be minimized, but not to the extent that it is currently feasible to easily produce ultra fine pitch multi-layer flexible interconnect with trace pitches at or under 0.030 mm, at high yield.

Accordingly, there is a need to provide ultra fine pitch multi-layer flexible interconnect and circuits having electrical, mechanical and thermal stability.

### BRIEF DESCRIPTION

In one aspect of the present technique a method for fabricating an interconnect is provided. The method comprises providing a carrier substrate, wherein the carrier substrate comprises a plurality of interconnect traces and a plurality of input/output contacts; providing a flexible substrate having a first side and a second side; disposing the second side of a sacrificial layer onto the first side of the flexible substrate to form a first assembly; disposing the carrier substrate onto the first assembly; and removing the carrier substrate and sacrificial layer to form the interconnect having the plurality of interconnect traces and the plurality of input/output contacts thereon.

In another aspect, an interconnect comprises a flexible substrate having a first side and a second side; and a plurality of interconnect traces having a pitch and a plurality of input/output contacts disposed on the second side of the flexible substrate, wherein the pitch comprises an interconnect trace and an interconnect space, and wherein the pitch is in a range from about 1 micron to about 20 microns.

In yet another aspect, a structure is provided which includes a carrier substrate; wherein the carrier substrate comprises a plurality of interconnect traces having a pitch and a plurality of input/output contacts, wherein the pitch comprises an interconnect trace and an interconnect space, and wherein the pitch is in a range from about 1 micron to about 20 microns; a flexible substrate having a first side and a second side; wherein the second side of the flexible substrate is disposed onto the carrier substrate; and a sacrificial layer having a first side and a second side, wherein the second side of the sacrificial layer is disposed on the first side of the flexible substrate.

In still another aspect, a detector for use in an imaging system is provided, which includes at least one sensor array configured for receiving waveform signals and converting the waveform signals to corresponding electrical signals; at least one electronic device configured for converting the electrical signals to corresponding digital signals; and an electronic circuit comprising an interconnect; wherein the interconnect comprises a flexible substrate having a first side and a second side; and a plurality of interconnect traces having a pitch and a plurality of input/output contacts disposed on the second side of the flexible substrate, wherein the pitch comprises an interconnect trace and an interconnect space, and wherein the pitch is in a range from about 1 micron to about 20 microns.

In yet another aspect, a method for fabricating an interconnect is provided. The method comprises providing a carrier substrate, wherein the carrier substrate comprises a plurality of interconnect traces and a plurality of input/output contacts; providing a flexible substrate having a first side and a second side, wherein the second side of the flexible substrate comprises a plurality of interconnect traces and a plurality of input/output contacts; providing a sacrificial layer having a first side and a second side; disposing the second side of the sacrificial layer onto the first side of the flexible substrate to form a first assembly; disposing the carrier substrate onto the first assembly; and removing the carrier substrate and the sacrificial layer to form the interconnect having the plurality of interconnect traces and the plurality of input/output contacts thereon.

In another aspect, a method for fabricating an interconnect is provided. The method comprises providing a first carrier substrate and a second carrier substrate, wherein the first and second carrier substrates comprise a plurality of interconnect traces and a plurality of input/output contacts; providing a flexible substrate having a first side and a second side; disposing the first carrier substrate onto the first side of the flexible substrate and disposing the second carrier substrate onto the second side of the flexible substrate; removing the first and second carrier substrates to form the interconnect having the plurality of interconnect traces and the plurality of input/output contacts thereon.

### DRAWINGS

These and other features, aspects, and advantages of the present invention will become better understood when the following detailed description is read with reference to the accompanying drawings in which like characters represent like parts throughout the drawings, wherein:

FIG. 1 is a diagrammatic representation of a carrier substrate employing a plurality of interconnect traces and input/output contacts according to one aspect of the present technique;

FIG. 2 is a diagrammatic representation of a sacrificial layer coupled to a stiffener disposed on a flexible substrate according to one embodiment of the present technique;

FIG. 3 is a diagrammatic representation of a sacrificial layer coupled to a stiffener disposed on a first side of a flexible substrate and a carrier substrate disposed on a second side of the flexible substrate according to one embodiment of the present technique;

FIG. 4 is a diagrammatic representation of a flexible substrate employing a plurality of interconnect traces and input/output contacts on a second side and a sacrificial layer and stiffener on a first side according to one embodiment of the present technique;

FIG. 5 is a diagrammatic representation of electronic devices disposed onto the input/output contacts on the second side of the flexible substrate according to one embodiment of the present technique;

FIG. 6 is a flow chart illustrating a method for fabricating an interconnect according to one aspect of the present technique; and

FIG. 7 is a flow chart illustrating a method for fabricating an interconnect according to another embodiment of the present technique; and

FIG. 8 is a diagrammatic representation of an exemplary X-ray imaging system, in accordance with one aspect of the present technique.

### DETAILED DESCRIPTION

Various embodiments of an interconnect and a device assembly employing the same are depicted and described herein by way of example. However, those skilled in the art will recognize that the interconnect and interconnect package presented can be employed in a wide variety of implementations to connect, for example, an integrated circuit device to another component, such as another integrated circuit device, a flexible interconnect, or a printed circuit board subsystem, etc. The claims presented herein are intended to encompass all such implementations.

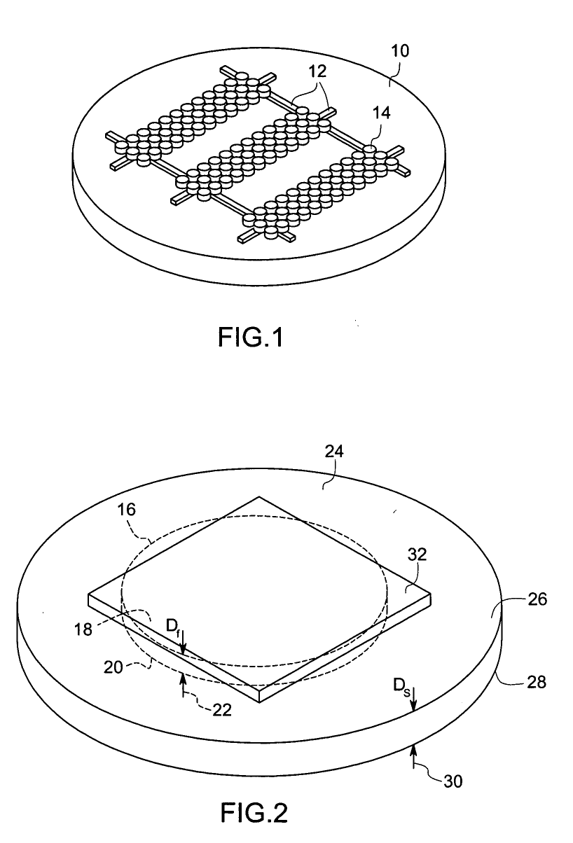

One aspect of the present technique described herein includes fabrication of an interconnect. Initially, a carrier substrate having a plurality of interconnect traces and a plurality of input/output (I/O) contacts is provided. FIG. 1 is an illustration of a carrier substrate 10 employing a plurality of interconnect traces 12 and a plurality of input/output (I/O) contacts 14, where a pitch is a sum of a space between two interconnect traces and a thickness of a single interconnect trace. In one embodiment, the pitch between two adjacent interconnect traces 16 is in a range from about 1 micron to about 20 microns. Advantageously, the carrier substrate 10 may be made of a material that is compatible with the device to which the interconnect is electrically coupled. This minimizes mechanical stress and strain, and provides a high reliability interconnect. Also, compatibility of the carrier substrate with the device provides for an electrical interconnect performance equivalent to that of the device. By way of example, if the device is an integrated circuit chip having a silicon substrate, then the carrier substrate may also be made of silicon. Selection of material for the carrier substrate 10 may also depend on the process capability, i.e., the pitch, thickness of an interconnect trace, and the distance between two adjacent interconnect traces. In addition, the selection of the material may also depend on electrical, mechanical, and thermal performance requirements of the circuit and/or device. In one embodiment, the carrier substrate includes a semiconductor material, such as, but not limited to, silicon, silicon carbide, and the like. In another embodiment, the carrier substrate 10 includes a non-semiconductor material, such as glass or quartz, for example.

Generally, standard wafer processes, such as, photolithography and wet chemistry are employed to create interconnect traces and I/O contacts on the carrier substrate 10. As previously described, mechanical and chemical stability of the rigid carrier substrate material may enable fabrication of interconnect traces having finer pitch than if the interconnect traces were fabricated directly onto a flexible substrate. That is to say that current techniques may provide for the fabrication of ultra dense interconnect traces having trace pitches on the order of approximately 1 micron to 20 microns. In accordance with embodiments of the present techniques, such ultra density interconnects may be initially fabricated onto a carrier substrate 10, which may then be transferred to a flexible substrate, as described further below.

FIG. 2 illustrates a flexible substrate 16 having a first side 18 and a second side 20. As discussed further below, an interconnect having interconnect traces 12 and I/O contacts 14 (FIG. 1) may be initially fabricated on a rigid substrate, such as the carrier substrate 10 and later transferred to the flexible substrate 16 interconnect. Flexible substrate 16 includes one or more layers of a polymer, such as, but not limited to, polyimide, polyetherimide, and combinations thereof. Further, the flexible substrate 16 has a thickness D_{f} 22 varying in a range from about 12 microns to about 50 microns. The flexible substrate 16 is disposed onto a sacrificial layer 24 having a first side 26 and a second side 28, and a thickness Dₛ 30 of about 500 microns to provide structural rigidity during fabrication. As will be appreciated, smaller values (e.g., less than 100 microns) of the thickness Ds facilitates conformity of the sacrificial layer 24 to enable the sacrificial layer 24 to acquire a predetermined shape.

The flexible substrate 16 is disposed on the sacrificial layer 24 such that the first side 18 of the flexible substrate 16 faces the second side 28 of the sacrificial layer 24. The sacrificial layer 24 provides mechanical support during the fabrication of the interconnect. As the name suggests, the sacrificial layer 24 is separated from the flexible substrate 16 when employing the interconnect in a device. In one embodiment, the sacrificial layer 24 while acting as a mechanical support for the flexible substrate 16 may include a frame or a plane surface. The sacrificial layer 24 may further include, integrated circuit, semiconductor wafer, a printed circuit board, ceramic substrate, and/or low density interconnect circuits.

Further, the sacrificial layer 24 may be further supported by a mechanical support in the form of a stiffener. As will be appreciated, the stiffener may provide additional mechanical support during fabrication. The stiffener 32 may include materials, such as, but not limited to, organic, polymer, ceramic, metal, semiconductor, glass, or combinations thereof. In one embodiment, the first side 26 of the sacrificial layer is coupled to the stiffener 32. As will be appreciated, in an alternate embodiment, the stiffener may be omitted.

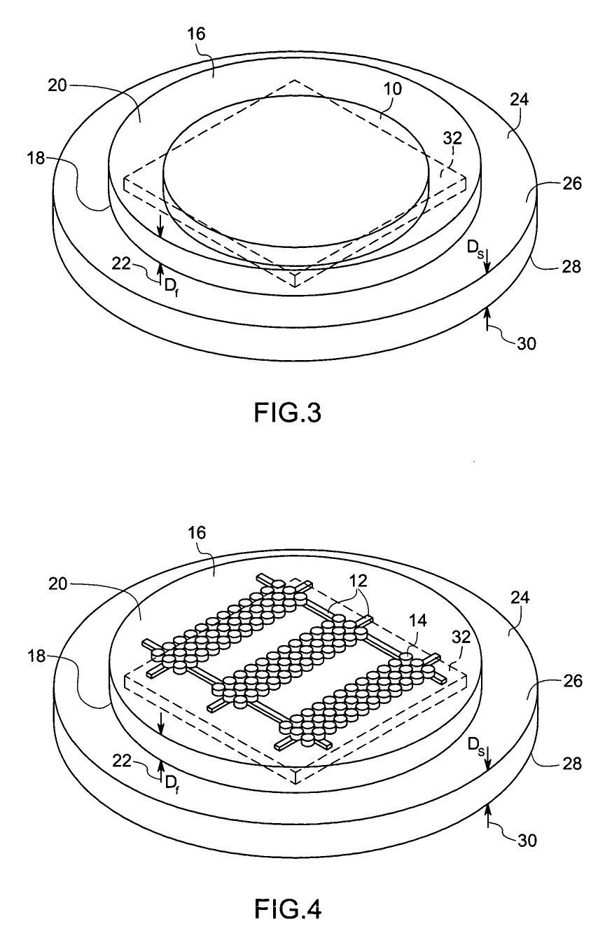

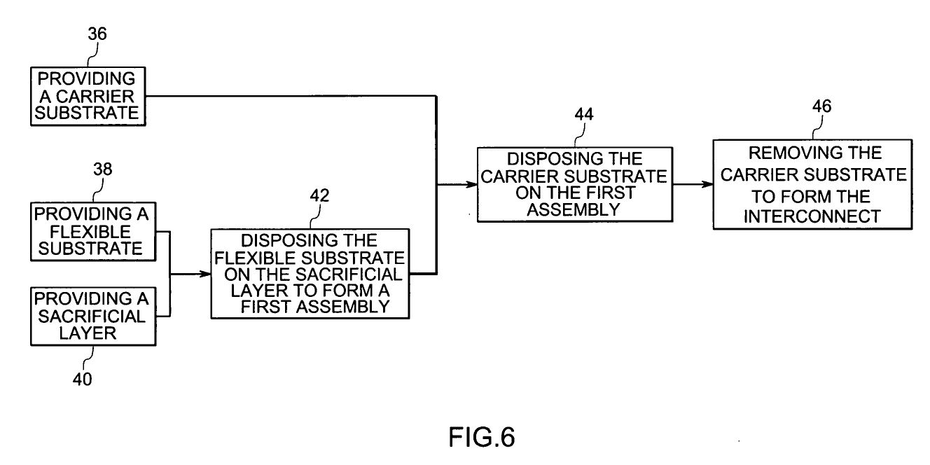

FIG. 3 illustrates a sacrificial layer 24 coupled to a stiffener and disposed on the first side 18 of the flexible substrate and the carrier substrate 10 disposed on the second side 20 of the flexible substrate. As further described below with reference to FIG. 6, in accordance with embodiments of the present techniques, once the interconnect is patterned on the carrier substrate 10, the carrier substrate 10 may be attached to the flexible substrate 16 using a polymeric adhesive, for example, such that the interconnect can be transferred directly to the flexible substrate 16. The carrier substrate 10 may be removed using mechanical and/or chemical etching techniques, such as chemical mechanical polishing (CMP), plasma, KOH, reactive ion etching (RIE), or Xenon Fluoride (XeF₂) etching, for example. The carrier substrate 10 is etched until only the interconnect remains on the flexible substrate 16, as illustrated in FIG. 4. FIG. 4 illustrates a flexible substrate employing a plurality of interconnect traces 12 and a plurality of I/O contacts 14 after removal of the carrier substrate 10 from the second side 20 of the flexible substrate 16.

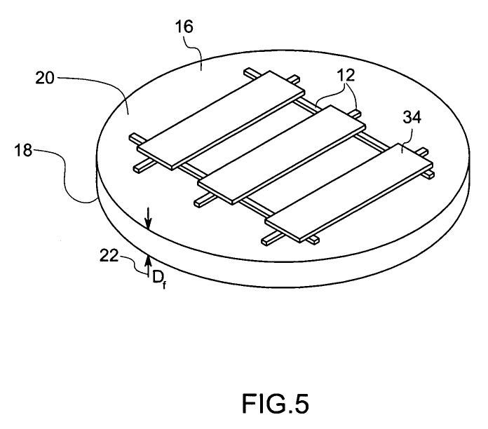

Further, the stiffener 32 and the sacrificial layer 24 may be etched using mechanical and/or chemical etching techniques, such as chemical mechanical polishing (CMP), plasma, KOH, reactive ion etching (RIE) or XeF₂ etching, for example. The stiffener 32 and sacrificial layer 24 are etched until the materials are completely removed from the flexible substrate 16, as illustrated in FIG. 5. FIG. 5 illustrates the flexible substrate 16 after the carrier substrate 10, the stiffener 32 and the sacrificial layer 24 have been etched. FIG. 5 also illustrates one or more electronic devices 34 being coupled to the I/O contacts 14 on the second side 20 of the flexible substrate 16.

FIG. 6 illustrates a flow chart for a method of fabricating an interconnect according to one aspect of the present technique. Step 36 includes providing the carrier substrate 10 having a plurality of interconnect traces 12 and a plurality of I/O contacts 14. Step 38 includes providing a flexible substrate which is adapted to receive the plurality of interconnect traces 12 and the plurality of I/O contacts 14 from the carrier substrate 10. Step 40 includes providing a sacrificial layer 24. In step 42, the second side 28 of the sacrificial layer 24 is disposed onto the first side 18 of the flexible substrate 16 to form a first assembly, which is mechanically stable and configured to receive carrier substrate 10.

In step 44, the carrier substrate 10 is disposed on the flexible substrate 16 of the first assembly and attached using an adhesive, such as, polymeric adhesive. Typical adhesive systems that may be employed to attach the carrier substrate 10 to the flexible substrate 16 for use in this application may include thermosetting materials such as epoxies and acrylics and thermoplastics such as polyimides or liquid crystal polymers. As described herein, the adhesive may be removed or be an integral component of the high density flexible interconnect. Material compatibility of the substrate release process is one of the key adhesive requirements. For example, using KOH to remove silicon requires an adhesive system to have etch selectivity for the thin flexible circuit integrity. Other release processes rely on de-bonding the carrier substrate from the interconnect circuit and the adhesive system utilized is critical

In step 56, the sacrificial layer 24 and the carrier substrate 10 are thinned in order to form an interconnect as shown in FIG. 5. Removing of the carrier substrate 10 may be achieved by mechanical processes, chemical processes, or a combination of mechanical and chemical processes. Non-limiting examples of such techniques include chemical-mechanical polishing, plasma etching, potassium hydroxide etching, reactive ion etching, xenon fluoride etching, and the like. In one embodiment, the sacrificial layer 24 is also thinned along with the carrier substrate 10. In this embodiment, the removing of the sacrificial layer 24 is done by etching the sacrificial layer 24 completely, whereas the carrier substrate 10 is etched to the extent that the interconnect traces 12 and the I/O contacts 14 on the carrier substrate remain intact. Since the carrier substrate is generally made of a robust material, it is easy to fabricate interconnect traces and I/O contacts at a fine pitch, which is otherwise difficult to fabricate on flexible substrates. The interconnect so formed may be used in various applications, such as those used in medical imaging, examples of which includes ultrasound imaging, computed tomography, X-ray imaging, MRI (magnetic resonance imaging); and in other applications, such as for example, optical sensors, digital cameras, and liquid crystal display devices.

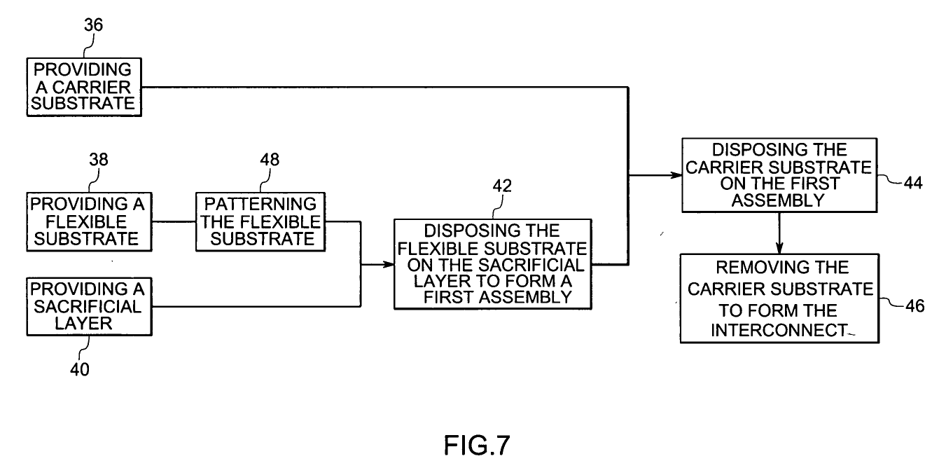

In another aspect of the present technique, one or more additional interconnect traces 12 and/or I/O contacts 14 on the second side 20 of the flexible substrate can be formed prior to attaching the carrier substrate 10 onto the second side 20 of the flexible substrate. FIG. 7 illustrates a flow chart for a method of fabricating an interconnect as described above in FIG. 6, along with an additional step 48, where the second side 20 of the flexible substrate 16 is patterned so as to form one or more interconnect traces 12 and/or I/O contacts 14.

In one embodiment, the interconnect so formed is used in a detector for an imaging system. The detector includes one or more sensor arrays configured for receiving waveform signals, such as, and converting the waveform signals to corresponding electrical signals. In an exemplary embodiment, the waveform signals may be X-ray signals that may be employed in computed tomography detector. In another exemplary embodiment, the waveform signals may be acoustic signals that may be employed in ultrasound detector. The detector also includes one or more electronic devices configured for converting the electrical signals to corresponding digital signals and an electronic circuit employing an interconnect described above.

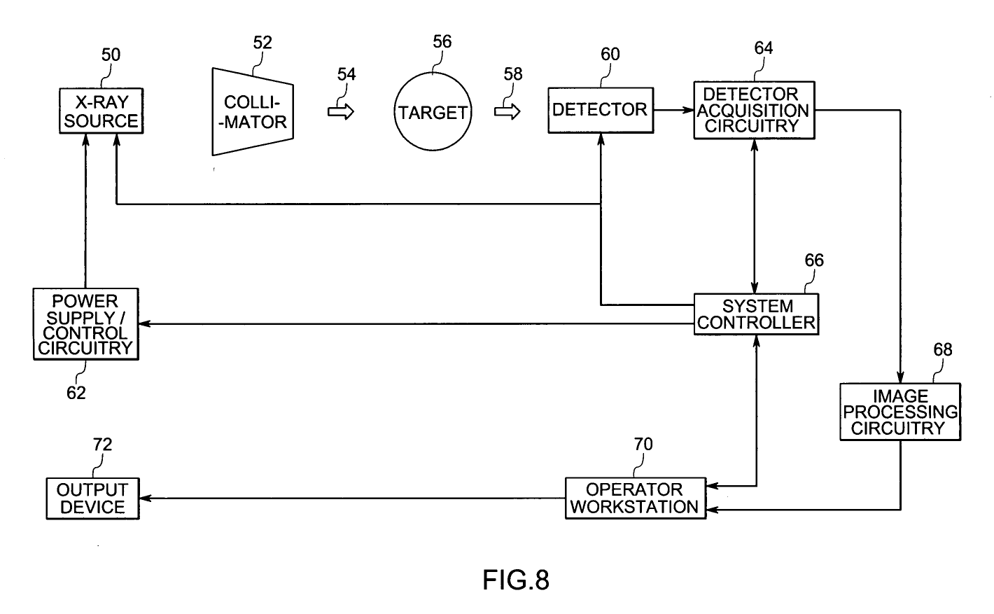

FIG. 8 is an illustration of an X-ray imaging system designed to acquire and process image data in accordance with the present technique. The X-ray imaging system includes an X-ray source 50 positioned adjacent to a collimator 14. In one embodiment. Collimator 52 permits a stream of X-ray radiation 54 to pass into a region in which a target 56, such as, human patient is positioned. A portion of the radiation is attenuated by the target 56. This attenuated radiation 58 impacts a detector 60. The detector 60 converts the X-ray photons incident on its surface to electrical signals that are acquired and processed to construct an image of the features within the target 56.

The X-ray source 50 is controlled by a power supply/control circuit 62 which furnishes both power and control signals for examination sequences. Moreover, detector 60 is coupled to detector acquisition circuitry 64, which commands acquisition of the signals generated in the detector 60. Detector acquisition circuitry 64 may also execute various signal processing and filtration functions, such as, for initial adjustment of dynamic ranges, interleaving of digital, and so forth.

In the depicted exemplary embodiment, one or both of the power supply/control circuit 62 and detector acquisition circuitry 64 are responsive to signals from a system controller 66. In some exemplary systems it may be desirable to move one or both of the detector 60 or the X-ray source 50. In such systems, a motor subsystem may also be present as a component of the system controller 66 to accomplish this motion. In the present example, the system controller 66 also includes signal processing circuitry, typically based upon a general purpose or application specific digital computer, associated memory circuitry for storing programs and routines executed by the computer, as well as configuration parameters and image data, interface circuits, and so forth.

Image processing circuitry 68 is also typically present in the X-ray imaging system. The image processing circuitry 68 receives acquired projection data from the detector acquisition circuitry 64 and processes the acquired data to generate one or more images based on X-ray attenuation.

One or more operator workstation 70 is also typically present in the X-ray imaging system. The operator workstation 70 allows an operator to initiate and configure an X-ray imaging examination and to view the images generated as part of the examination. For example, the system controller 66 is generally linked to operator workstation 70 so that an operator, via one or more input devices associated with the operator workstation 70, may provide instructions or commands to the system controller 66.

Similarly, the image processing circuitry 68 is linked to the operator workstation 70 such that the operator workstation 70 may receive and display the output of the image processing circuitry 68 on an output device 72, such as a display or printer. The output device 72 may include standard or special purpose computer monitors and associated processing circuitry. In general, displays, printers, operator workstations, and similar devices supplied within the system may be local to the data acquisition components or may be remote from these components, such as elsewhere within an institution or hospital or in an entirely different location. Output devices and operator workstations that are remote from the data acquisition components may be linked to the image acquisition system via one or more configurable networks, such as the internet, virtual private networks, and so forth. As will be appreciated by one of ordinary skill in the art, though the system controller 66, image processing circuitry 68, and operator workstation 70 are shown distinct from one another in FIG. 8, these components may actually be embodied in a single processor-based system, such as a general purpose or application specific digital computer. Alternatively, some or all of these components may be present in distinct processor-based systems, such as a general purpose or application specific digital computers, configured to communicate with one another. For example, the image processing circuitry 68 may be a component of a distinct reconstruction and viewing workstation.

While only certain features of the invention have been illustrated and described herein, many modifications and changes will occur to those skilled in the art. It is, therefore, to be understood that the appended claims are intended to cover all such modifications and changes as fall within the true spirit of the invention.

1. A method for fabricating an interconnect comprising:
providing a carrier substrate, wherein the carrier substrate comprises a plurality of interconnect traces and a plurality of input/output contacts;
providing a flexible substrate having a first side and a second side;
providing a sacrificial layer having a first side and a second side;
disposing the second side of the sacrificial layer onto the first side of the flexible substrate to form a first assembly;
disposing the carrier substrate onto the first assembly; and
removing the carrier substrate such that only the plurality of interconnect traces and the plurality of input/output contacts remain on the flexible substrate.

2. The method according to claim 1, wherein the carrier substrate comprises a semiconductor material.

3. The material according to claim 2, wherein the semiconductor material comprises silicon or silicon carbide.

4. The method according to claim 1, wherein the carrier substrate comprises a non-semiconductor material.

5. The method according to claim 4, wherein the non-semiconductor material comprises glass.

6. The method according to claim 4, wherein the non-semiconductor material comprises quartz.

7. The method according to claim 1, wherein the flexible substrate comprises one or more layers of a polymer.

8. The method according to claim 7, wherein the polymer comprises a polyimide, polyetherimide, or combinations thereof.

9. The method according to claim 1, wherein the sacrificial wafer comprises a printed circuit board.

10. The method according to claim 1, wherein the sacrificial wafer comprises a ceramic substrate.

11. The method according to claim 1, wherein the sacrificial wafer comprises a low density interconnect circuit.

12. The method according to claim 1, wherein the sacrificial wafer comprises a mechanical support.

13. The method according to claim 1, wherein removing the carrier substrate comprises at least one of chemical mechanical polishing, reactive ion etching, plasma etching, dry etching, and combinations thereof.

14. The method according to claim 1 further comprising coupling a stiffener to the first side of the sacrificial layer.

15. The method according to claim 14, wherein the stiffener comprises organic, polymer, ceramic, metal, semiconductor, glass, or combinations thereof.

16. An interconnect comprising:
a flexible substrate having a first side and a second side; and
a plurality of interconnect traces having a pitch and a plurality of input/output contacts disposed on the second side of the flexible substrate, wherein the pitch comprises an interconnect trace and an interconnect space, and wherein the pitch is in a range from about 1 microns to about 20 microns.

17. The interconnect according to claim 16, wherein the flexible substrate comprises one or more layers of a polymer.

18. The interconnect according to claim 17, wherein the polymer comprises polyimide, polyetherimide, or combinations thereof.

19. The interconnect according to claim 16, wherein the pitch is in a range from about 1 micron to about 20 microns.

20. The interconnect according to claim 16, wherein the interconnect is electronically coupled to at least two electronic devices.

21. The interconnect according to claim 20, wherein the at least two electronic devices comprises imaging equipments, optical sensors, digital cameras, liquid crystal displays, and combinations thereof.

22. A structure comprising:
a carrier substrate; wherein the carrier substrate comprises a plurality of interconnect traces having a pitch and a plurality of input/output contacts, wherein the pitch comprises an interconnect trace and an interconnect space, and wherein the pitch is in a range from about 1 microns to about 20 microns;
a flexible substrate having a first side and a second side, wherein the second side of the flexible substrate is disposed onto the carrier substrate; and
a sacrificial layer having a first side and a second side, wherein the second side of the sacrificial layer is disposed on the first side of the flexible substrate.

23. The structure according to claim 22, wherein the pitch is in a range from about 1 micron to about 20 microns.

24. The structure according to claim 22, further comprising a stiffener coupled to the first side of the sacrificial layer.

25. The structure according to claim 24, wherein the stiffener comprises organic, polymer, ceramic, metal, semiconductor, glass, or combinations thereof.

26. The structure according to claim 22, wherein the flexible substrate comprises one or more layers of a polymer.

27. The structure according to claim 26, wherein the polymer comprises polyimide, polyetherimide, or combinations thereof.

28. The structure according to claim 22, wherein the interconnect is electronically coupled to at least two electronic devices.

29. The structure according to claim 28, wherein the at least two electronic devices comprises imaging equipments, optical sensors, digital cameras, liquid crystal displays, and combinations thereof.

30. A detector module for use in an imaging system, the detector module comprising:
at least one sensor array configured for receiving waveform signals and converting the waveform signals to corresponding electrical signals;
at least one electronic device configured for converting the electrical signals to corresponding digital signals; and
an electronic circuit comprising an interconnect;
wherein the interconnect comprises a flexible substrate having a first side and a second side; and a plurality of interconnect traces having a pitch and a plurality of input/output contacts disposed on the second side of the flexible substrate, wherein the pitch comprises an interconnect trace and an interconnect space, and wherein the pitch is in a range from about 1 micron to about 20 microns.

31. The detector module according to claim 30, wherein the waveform signals comprises X-ray signals.

32. The detector module according to claim 31, comprising a computed tomography detector.

33. The detector module according to claim 30, wherein the waveform signals comprises acoustic signals.

34. The detector module according to claim 33, comprising an ultrasound detector.

35. The detector according to claim 30, wherein the flexible substrate comprises one or more layers of a polymer.

36. The detector according to claim 35, wherein the polymer comprises polyimide, polyetherimide, or combinations thereof.

37. The detector according to claim 30, wherein the pitch is in a range from about 1 micron to about 20 microns.

38. The detector according to claim 30, wherein the interconnect is electronically coupled to at least two electronic devices.

39. The detector according to claim 38, wherein the at least two electronic devices comprises imaging equipments, optical sensors, digital cameras, and liquid crystal displays.

40. A method for fabricating an interconnect comprising:
providing a carrier substrate, wherein the carrier substrate comprises a plurality of interconnect traces and a plurality of input/output contacts;
providing a flexible substrate having a first side and a second side, wherein the second side of the flexible substrate comprises a plurality of interconnect traces and a plurality of input/output contacts;
providing a sacrificial layer having a first side and a second side;
disposing the second side of the sacrificial layer onto the first side of the flexible substrate to form a first assembly;
disposing the carrier substrate onto the first assembly; and
removing the sacrificial layer and the carrier substrate to form the interconnect having the plurality of interconnect traces and the plurality of input/output contacts thereon.

41. A method of fabricating an interconnect comprising:
providing a carrier substrate having an interconnect fabricated thereon;
coupling the carrier substrate to a flexible substrate, such that the interconnect is disposed directly onto the carrier substrate; and
removing the carrier substrate such that only the interconnect remains on the flexible substrate.

42. The method according to claim 41, wherein providing the carrier substrate comprises providing the carrier substrate having an interconnect thereon, wherein the interconnect comprises a plurality of traces and input/output contacts.

43. The method according to claim 41, wherein coupling the carrier substrate to the flexible substrate comprises attaching the carrier substrate to the flexible substrate using a polymeric adhesive.

44. The method according to claim 43, wherein the polymeric adhesive comprises a thermosetting material.

45. The method according to claim 44, wherein the thermosetting material comprises an epoxy, or an acrylic, or combinations thereof.

46. The method according to claim 43, wherein the polymeric adhesive comprises a thermoplastic material.

47. The method according to claim 46, wherein the thermoplastic material comprises a polyamide, or liquid crystal polymers.

48. The method according to claim 41, wherein removing the carrier substrate comprises etching the carrier substrate.

49. A method for fabricating an interconnect comprising:
providing a first carrier substrate and a second carrier substrate, wherein the first and second carrier substrates comprise a plurality of interconnect traces and a plurality of input/output contacts;
providing a flexible substrate having a first side and a second side;
disposing the first carrier substrate onto the first side of the flexible substrate and disposing the second carrier substrate onto the second side of the flexible substrate; and
removing the first and second carrier substrates to form the interconnect having the plurality of interconnect traces and the plurality of input/output contacts thereon.

50. The method according to claim 49, wherein at least one of the first and second sides of the flexible substrate comprises plurality of interconnect traces and a plurality of input/output contacts.
